(19) United States
(12) Patent Application Publication
(10) Pub. No.: US 2022/0065727 A1
(43) Pub. Date: Mar. 3, 2022

(54) Coolant Microleak Sensor for a Vacuum System

(71) Applicant: KLA Corporation, Milpitas, CA (US)

(72) Inventors: Nadir S. Faradzhev, Los Gatos, CA (US); Michael Sushchikh, San Jose, CA (US); Salam Harb, Los Gatos, CA (US)

(21) Appl. No.: 17/408,106

(22) Filed: Aug. 20, 2021

Related U.S. Application Data
(60) Provisional application No. 63/071,373, filed on Aug. 28, 2020.

(51) Int. Cl. G01M 3/22; G01M 3/28; G01M 3/20; G01M 3/38; H05K 7/20; H01J 37/26

(52) U.S. Cl. CPC G01M 3/22; G01M 3/2815; H01J 37/261; G01M 3/38; H05K 7/20281; G01M 3/202

(57) ABSTRACT

A system includes a vacuum chamber and a component, disposed in the vacuum chamber, that heats up during operation. The system also includes a cooling line, mechanically coupled to the component, to circulate coolant to cool the component during operation. The system further includes a vacuum gauge to measure a total pressure in the vacuum chamber and an analyzer to measure a partial pressure in the vacuum chamber of a substance that can leak from the cooling line.

### RELATED APPLICATION

This application claims priority to U.S. Provisional Patent Application No. 63/071,373, filed on Aug. 28, 2020, which is incorporated by reference in its entirety for all purposes.

### TECHNICAL FIELD

This disclosure relates to cooling lines in vacuum systems, and more specifically to sensing coolant leaks from the cooling lines.

### BACKGROUND

Cooling lines in vacuum chambers can develop microleaks, for example as a result of stress from mechanical motion. If left undetected, a microleak can grow until it turns into a catastrophic leak. Damage from a catastrophic leak requires extensive repair and causes lengthy downtime. Using a vacuum gauge to monitor the total vacuum pressure in a vacuum chamber may be insufficient to identify a microleak in a cooling line, because the vacuum gauge cannot differentiate the microleak from some other leak or from outgassing sources in the vacuum chamber.

### SUMMARY

According, there is a need for methods and systems to detect coolant microleaks in vacuum systems, so that the cooling line can be repaired before a catastrophic leak occurs.

In some embodiments, a system includes a vacuum chamber and a component, disposed within the vacuum chamber, that heats up during operation. The system also includes a cooling line, mechanically coupled to the component, to circulate coolant to cool the component during operation. The system further includes a vacuum gauge to measure a total pressure in the vacuum chamber and an analyzer to measure a partial pressure in the vacuum chamber of a substance that can leak from the cooling line.

In some embodiments, a method includes operating a component disposed in a vacuum chamber. Operating the component causes heating. The method also includes circulating coolant through a cooling line mechanically coupled to the component, to cool the component. The method further includes measuring a total pressure in the vacuum chamber; measuring a partial pressure in the vacuum chamber of a substance that can leak from the cooling line; and determining, based on the partial pressure, whether the cooling line has a leak.

### BRIEF DESCRIPTION OF THE DRAWINGS

For a better understanding of the various described implementations, reference should be made to the Detailed Description below, in conjunction with the following drawings.

FIG. 1A is a block diagram showing a vacuum system with a cooling line that contains coolant and a marker species, in accordance with some embodiments.

FIG. 1B is a block diagram showing an example of the vacuum system of FIG. 1A in which a microcrack or fracture has formed in the cooling line, in accordance with some embodiments.

FIG. 2A is a block diagram showing a vacuum system with a cooling line that contains coolant without a marker species, in accordance with some embodiments.

FIG. 2B is a block diagram showing an example of the vacuum system of FIG. 2A in which a microcrack or fracture has formed in the cooling line, in accordance with some embodiments.

FIG. 3 is a flowchart illustrating a method of detecting a cooling-line leak in a vacuum system, in accordance with some embodiments.

Like reference numerals refer to corresponding parts throughout the drawings and specification.

### DETAILED DESCRIPTION

Reference will now be made in detail to various embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

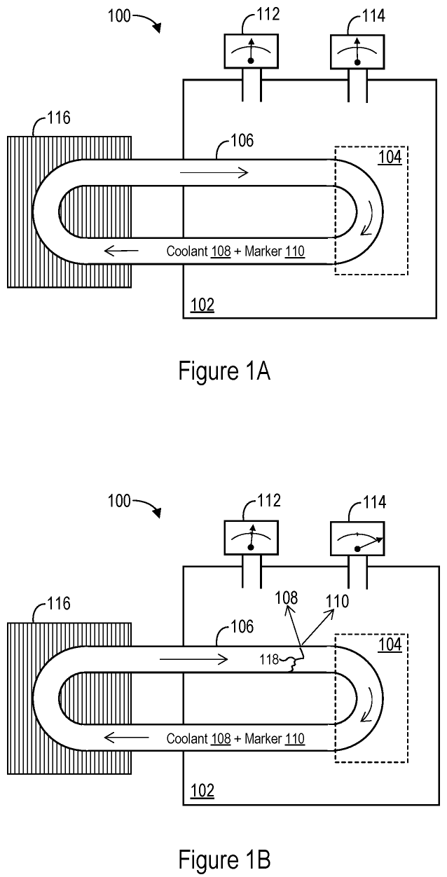

FIG. 1A is a block diagram showing a vacuum system 100 in accordance with some embodiments. The vacuum system 100 includes a vacuum chamber 102. In some embodiments, the vacuum chamber 102 provides an ultra-high vacuum (UHV). (UHV is a standard, well-known technical term that refers to vacuums with a pressure on the order of 10⁻⁹ torr or lower.) The vacuum system 100 may be a semiconductor inspection or metrology system. For example, the vacuum system 100 may be a scanning electron microscope (SEM). The vacuum system may include EUV optics for semiconductor inspection or metrology (i.e., optics for 13.5 nm light). Alternatively, the vacuum system 100 may have a different application.

A component 104 is disposed within the vacuum chamber 102. The component 104 heats up during operation. For example, the component 104 is an active component that consumes power and heats up as a result (as opposed to a passive component that does not consume power). In another example, the component 104 is mechanically and thermally coupled, directly or indirectly, to an active component, such that heating of the active component also heats up the component 104.

In some embodiments, the component 104 is a motor or includes a motor. The cooling line 106 may be mechanically connected to the motor (e.g., to a motor coil in the motor) to cool the motor. The motor, for example, may be a stage motor that translates a stage disposed in the vacuum chamber 102. The stage may have a chuck mounted on it for supporting a substrate (e.g., a semiconductor wafer). The stage translates the chuck. Operating the motor thus causes the stage, and therefore the chuck and the substrate, to be translated to a desired position.

In some embodiments, the component 104 is or includes a digital camera. For example, the camera is used to image a substrate (e.g., a semiconductor wafer). The cooling line 106 may be mechanically connected to the digital camera, to cool the digital camera.

In some embodiments, the component 104 is or includes electron optics (e.g., a lens for electron optics, such as a magnetic lens). The cooling line 106 may be mechanically connected to the electron optics (e.g., to the lens), to cool the electron optics.

A cooling line 106 is mechanically (and thermally) coupled to the component 104. While the cooling line 106 is shown as a single loop in FIG. 1A, it may include a coolant manifold that branches in the vacuum chamber 102. Coolant 108 circulates in the cooling line 106 during operation of the system 100 to cool the component 104. By cooling the component 104, the circulating coolant 108 also indirectly cools other components in the vacuum chamber 102 that would otherwise be heated by heat from the component 104. For example, if the vacuum chamber 102 includes optical components (e.g., EUV optics) (e.g., electron optics, such as a magnetic lens or other electron-optics lens). thermally coupled to the component 104, then the circulating coolant 108 indirectly cools the optical components.

In some embodiments, the vacuum system 100 includes a chiller 116 disposed outside of the vacuum chamber 102. The cooling line 102 extends out of the vacuum chamber 102, through the chiller 116, and back into the vacuum chamber 102. The chiller 116 chills the coolant 108 that has been warmed up by the component 104 and thus has carried away heat from the component 104.

The cooling line 106 may be flexible, to accommodate movement of the component 104 (e.g., movement of a motor). In some embodiments, the cooling line 106 is made of polymer in whole or in part. For example, the cooling line 106 may be flexible plastic in whole or in part. Alternatively, the cooling line 106 is made of another material in whole or in part, such as metal or an elastomer.

In some embodiments, the coolant 108 is or includes ordinary water (H₂O). Ordinary water is distinct from heavy water. Both hydrogen atoms in a molecule of ordinary water are ordinary hydrogen with a single proton and no neutron. Examples of heavy water, by contrast, include deuterium oxide (D₂O), in which both hydrogen atoms in a molecule are deuterium atoms, and hydrogen-deuterium oxide (HDO), in which one hydrogen atom in a molecule is ordinary hydrogen and the other is deuterium.

The vacuum system 100 includes a vacuum gauge 112 that measures the total pressure in the vacuum chamber 112. The vacuum gauge 112 may have insufficient sensitivity, however, to detect a microcrack or fracture 118 in the cooling line 106. The microcrack or fracture 118 results in a microleak: coolant 108 leaks from the cooling line 106 through the microcrack or fracture 118, as shown in FIG. 1B. The microleak may not have sufficient magnitude to increase the total pressure of the vacuum chamber 102 by an amount that indicates the presence of the microleak. By the time the vacuum gauge 112 can detect the leaking coolant 108, the microleak may have turned into a catastrophic leak that causes severe damage to the vacuum chamber 102 and/or to a product (e.g., a substrate, such as a semiconductor wafer) in the vacuum chamber 102.

For example, if the coolant 108 is ordinary water, leaking water 108 from the cooling line 106 may be only one of multiple sources of water vapor in the vacuum chamber 102. Water may also outgas from elastomer seals (e.g., O-rings) used to seal the vacuum chamber 102. And other substances besides water may be present at respective partial pressures in the vacuum chamber 102. The vacuum gauge 112 measures the total pressure in the vacuum chamber 102, and thus cannot detect the degree to which water contributes to the total pressure (i.e., cannot detect the partial pressure of water in the vacuum chamber 102). The vacuum gauge 112 also cannot detect the degree to which water comes from the microcrack or fracture 118 as opposed to another source.

In some embodiments, to solve these problems, the cooling line 106 contains a marker species 110 in addition to the coolant 108. The marker species 110 circulates in the cooling line 106 along with the coolant 108. The marker species 110 is a substance (e.g., a molecule) that can leak from the cooling line 106 in the event of a microcrack or fracture 118, as shown in FIG. 1B. The marker species 110 may be chosen such that it is unique to the composition of residual gasses in the vacuum chamber 102 (i.e., it is absent from the vacuum chamber 102 except in the event of a leak from the cooling line 106). The vacuum system 100 includes an analyzer 114 configured to measure the partial pressure of the marker species 110 in the vacuum chamber 102. The analyzer 114 can detect the microleak from the microcrack or fracture 118 before the microcrack or fracture 118 spreads or grows to a point that the vacuum gauge 112 can detect it (e.g., before catastrophic failure occurs), because it measures the partial pressure of the marker species 110 as opposed to the total pressure of the vacuum chamber 102. As comparison of the readings of the vacuum gauge 112 and analyzer 114 in FIGS. 1A and 1B shows, the microcrack or fracture 118 causes a significantly larger increase in the partial pressure of the marker species 110 than of the total pressure of the vacuum chamber 102. Detection of the microleak from the microcrack or fracture 118 may occur when the partial pressure of the marker species 110 satisfies a threshold (e.g., exceeds, or equals or exceeds, a specified value, or increases by at least, or more than, a specified amount). The analyzer 114 may be communicatively coupled to a computer system that generates a warning signal in response to detection of the microleak from the microcrack or fracture 118. The vacuum chamber 102 may then be taken offline in a controlled manner and the cooling line 106 repaired. In some embodiments, the analyzer 114 is a residual gas analyzer (RGA) (e.g., a mass spectrometer). In some embodiments, the analyzer 114 includes an infrared spectrometer that performs infrared spectroscopy (e.g., Fourier transform infrared spectroscopy (FTIR)).

In some embodiments, the marker species 110 is heavy water. For example, the coolant 108 is H₂O, and D₂O is added to the coolant 108 in the cooling line 106. The D₂O reacts with the H₂O to produce HDO, which is the marker species 110. The analyzer 114 is configured to detect HDO.

In some embodiments, 1-propanol is added to the coolant 108 (e.g., which is H₂O) to provide the marker species 110. The marker species 110 thus corresponds to 1-propanol. The analyzer 114 is configured to detect the peak that results from the addition of 1-propanol to the coolant 108 in the presence of a microcrack or fracture 118.

The marker species 110 may be chosen such that it does not react with the coolant 108. The marker species 110 thus is added to the coolant 108. Alternatively, a chemical is added to the coolant 108 that reacts with the coolant 108 to create the marker species 110. The marker species 110 may be chosen such that it has a specific heat capacity within ±50% of that of the coolant to provide the desired cooling of the component 104. The marker species 110 may be chemically inert, to avoid causing corrosion in the cooling line 106 and chiller 116. The marker species 110 may have a vapor pressure within ±50% of the vapor pressure of the coolant 108, so that the marker species 110 and the coolant 108 have similar flow rates into the vacuum chamber 102 in the event that a microcrack or fracture 118 forms.

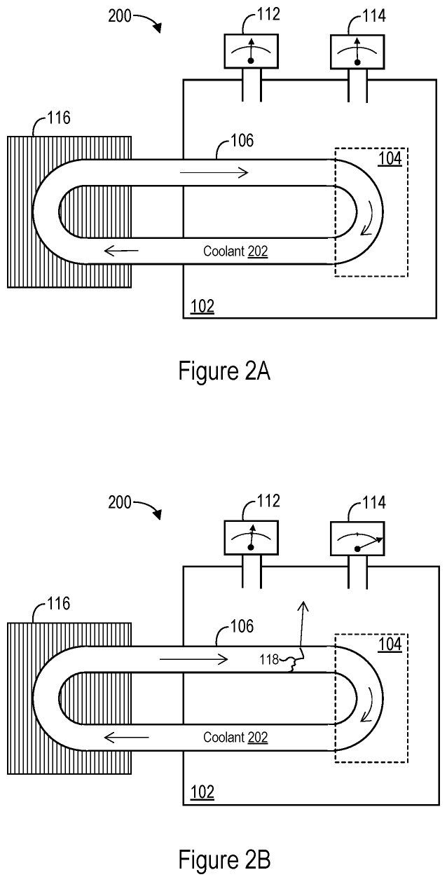

In some embodiments, a coolant is used that is not otherwise present in the vacuum chamber 102 (i.e., is unique to the composition of residual gasses in the vacuum chamber 102) and thus is absent from the vacuum chamber 102 except in the event of a leak from the cooling line 106 (e.g., in the event that a microcrack or fracture 118 forms on the cooling line 106). Such coolant may be used without a marker species 110. FIGS. 2A and 2B show a vacuum system 200 that uses this type of coolant, in accordance with some embodiments. In the vacuum system 200, no marker species 110 is used and the coolant 108 is replaced with a coolant 202 that is absent from the vacuum chamber 102 except in the event of a leak from the cooling line 106. In FIG. 2A the cooling line 206 is intact, while FIG. 2B shows a microcrack or fracture 118 that has formed on the cooling line 106. The analyzer 114 is configured to detect the coolant 202. The analyzer 114 thus may detect the microcrack or fracture 118 (i.e., detect the microleak resulting from the microcrack or fracture 118).

The coolant 202 may be a fluorocarbon-based fluid. For example, the coolant 202 may be a perfluorinated compound (PFC) such as those sold under the FLUORINERT® brand name. Alternatively, the coolant 202 may be a segregated hydrofluoroether (HFE) compound or a fluroketone (FK) compound such as those sold under the NOVEC® brand name.

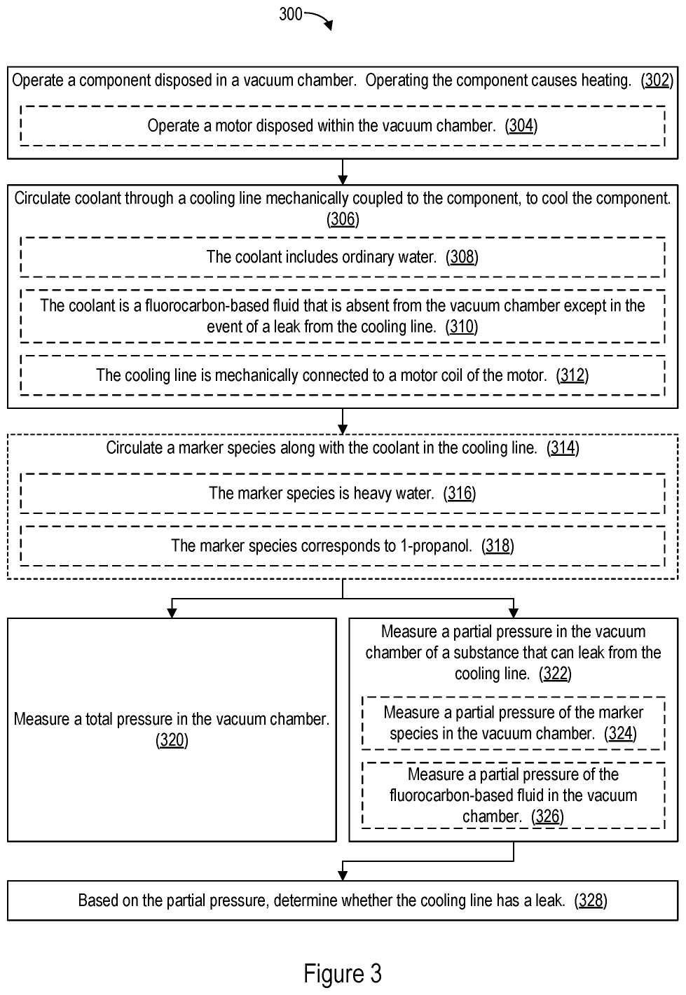

FIG. 3 is a flowchart illustrating a method 300 of detecting a cooling-line leak (e.g., a microleak from a microcrack or fracture 118) in a vacuum system (e.g., vacuum system 100, FIGS. 1A-1B; vacuum system 200, FIGS. 2A-2B), in accordance with some embodiments. While the steps in the method 300 are shown and described in a specific order, the steps may be performed in parallel. For example, all of the steps in the method 300 may be performed simultaneously in an ongoing manner.

In the method 300, a component (e.g., component 104) that is disposed in a vacuum chamber (e.g., vacuum chamber 102) is operated (302). Operating the component causes heating (e.g., causes the component to heat up). In some embodiments, operating the component includes operating (304) a motor disposed within the vacuum chamber. For example, a motor is operated to translate a stage on which a chuck is mounted. The chuck supports a substrate (e.g., a semiconductor wafer). In some other embodiments, operating the component includes operating a digital camera disposed within the vacuum chamber and/or operating electron optics (e.g., a magnetic lens or other electron-optics lens) disposed within the vacuum chamber.

To cool the component, coolant (e.g., coolant 108, FIGS. 1A-1B; coolant 202, FIGS. 2A-2B) is circulated (306) through a cooling line (e.g., cooling line 106) that is mechanically coupled to the component. In some embodiments, the coolant (e.g., coolant 108, FIGS. 1A-1B) includes (308) ordinary water. Alternatively, the coolant (e.g., coolant 202, FIGS. 2A-2B) may be (310) a fluorocarbon-based fluid (e.g., a fluid such as those sold under the FLUORINERT® or NOVEC® brand) that is absent from the vacuum chamber except in the event of a leak from the cooling line.

In some embodiments, the cooling line is mechanically connected (312) to a motor coil of the motor. In some embodiments, the cooling line is mechanically connected to the digital camera and/or to the electron optics.

In some embodiments, a marker species (e.g., marker species 110, FIGS. 1A-1B) is circulated (314) along with the coolant in the cooling line. For example, the marker species is (316) heavy water (e.g., HDO). In another example, the marker species corresponds (318) to 1-propanol (e.g., results from the addition of 1-propanol to the coolant 108).

A total pressure in the vacuum chamber is measured (320). For example, the total pressure is measured using a vacuum gauge 112.

A partial pressure in the vacuum chamber of a substance that can leak from the cooling line is measured (322). For example, a partial pressure of the marker species in the vacuum chamber is measured (324). In another example, a partial pressure of the fluorocarbon-based fluid in the vacuum chamber is measured (326). The partial pressure is measured using an analyzer 114. In some embodiments, the partial pressure is measured using mass spectrometry. Alternatively, the partial pressure may be measured using infrared spectroscopy (e.g., Fourier transform infrared spectroscopy (FTIR)).

The method 300 allows for early detection of a microcrack or fracture in a cooling line (e.g., coolant manifold) of a vacuum system. The microcrack or fracture can then be repaired in an orderly manner by shutting down the vacuum system before catastrophic damage occurs.

The foregoing description, for purpose of explanation, has been described with reference to specific embodiments. However, the illustrative discussions above are not intended to be exhaustive or to limit the scope of the claims to the precise forms disclosed. Many modifications and variations are possible in view of the above teachings. The embodiments were chosen in order to best explain the principles underlying the claims and their practical applications, to thereby enable others skilled in the art to best use the embodiments with various modifications as are suited to the particular uses contemplated.

What is claimed is:

1. A system, comprising:
a vacuum chamber;
a component, disposed in the vacuum chamber, that heats up during operation;
a cooling line, mechanically coupled to the component, to circulate coolant to cool the component during operation;
a vacuum gauge to measure a total pressure in the vacuum chamber; and
an analyzer to measure a partial pressure in the vacuum chamber of a substance that can leak from the cooling line.

2. The system of claim 1, wherein the cooling line comprises a coolant manifold in the vacuum chamber.

3. The system of claim 1, further comprising a chiller to chill the coolant in the cooling line, wherein:
the chiller is disposed outside of the vacuum chamber; and
the cooling line extends out of the vacuum chamber, through the chiller, and back into the vacuum chamber.

4. The system of claim 1, wherein:
the cooling line contains the coolant and further contains a marker species; and
the marker species is the substance that can leak from the cooling line.

5. The system of claim 4, wherein the coolant comprises ordinary water.

6. The system of claim 5, wherein the marker species is heavy water.

7. The system of claim 5, wherein the marker species corresponds to 1-propanol.

8. The system of claim 1, wherein:
the coolant comprises a fluorocarbon-based fluid that is absent from the vacuum chamber except in the event of a leak from the cooling line; and
the substance that can leak from the cooling line is the fluorocarbon-based fluid.

9. The system of claim 1, wherein:
the component comprises a motor disposed within the vacuum chamber; and
the motor comprises a motor coil to which the cooling line is mechanically connected, to cool the motor coil.

10. The system of claim 9, further comprising:
a chuck to support a substrate; and
a translatable stage, on which the chuck is mounted, to translate the chuck;
wherein the motor is a stage motor to translate the stage.

11. The system of claim 10, wherein the vacuum chamber is a vacuum chamber in a scanning electron microscope (SEM).

12. The system of claim 10, further comprising extreme ultraviolet (EUV) optics disposed within the vacuum chamber.

13. The system of claim 10, further comprising electron optics disposed within the vacuum chamber, the electron optics comprising a magnetic lens.

14. The system of claim 1, wherein:
the component comprises a magnetic lens; and
the cooling line is mechanically connected to the magnetic lens, to cool the magnetic lens.

15. The system of claim 1, wherein:
the component comprises a digital camera disposed within the vacuum chamber; and
the cooling line is mechanically connected to the digital camera, to cool the digital camera.

16. The system of claim 1, wherein the analyzer comprises a mass spectrometer.

17. The system of claim 1, wherein the analyzer comprises an infrared spectrometer.

18. The system of claim 1, wherein the cooling line comprises flexible plastic.

19. A method, comprising:
operating a component disposed in a vacuum chamber, wherein operating the component causes heating;
circulating coolant through a cooling line mechanically coupled to the component, to cool the component;
measuring a total pressure in the vacuum chamber;
measuring a partial pressure in the vacuum chamber of a substance that can leak from the cooling line; and
based on the partial pressure, determining whether the cooling line has a leak.

20. The method of claim 19, further comprising circulating a marker species along with the coolant in the cooling line;
wherein measuring the partial pressure comprises measuring a partial pressure of the marker species in the vacuum chamber.

21. The method of claim 20, wherein the coolant comprises ordinary water.

22. The method of claim 21, wherein the marker species is heavy water.

23. The method of claim 21, wherein the marker species corresponds to 1-propanol.

24. The method of claim 19, wherein:
circulating the coolant comprises circulating, in the cooling line, a fluorocarbon-based fluid that is absent from the vacuum chamber except in the event of a leak from the cooling line; and
measuring the partial pressure comprises measuring a partial pressure of the fluorocarbon-based fluid in the vacuum chamber.

25. The method of claim 19, wherein operating the component comprises operating a motor disposed within the vacuum chamber, the cooling line being mechanically connected to a motor coil of the motor.

26. The method of claim 25, wherein operating the motor comprises translating a stage on which is mounted a chuck supporting a substrate.

27. The method of claim 19, wherein measuring the partial pressure comprises performing mass spectrometry.

28. The method of claim 19, wherein measuring the partial pressure comprises performing infrared spectroscopy.
